(19) United States
(12) Patent Application Publication
(10) Pub. No.: US 2025/0076195 A1
(43) Pub. Date: Mar. 6, 2025

(54) Method for Monitoring Ghost Image of Illumination Unit of Lithography Machine

(71) Applicant: Shanghai Huali Microelectronics Corporation, Shanghai (CN)

(72) Inventors: Kaifeng Xu, Shanghai (CN); Haichang Zheng, Shanghai (CN)

(73) Assignee: Shanghai Huali Microelectronics Corporation, Shanghai (CN)

(21) Appl. No.: 18/369,939

(22) Filed: Sep. 19, 2023

(30) Foreign Application Priority Data
Aug. 30, 2023 (CN) 202311112388.X

(51) Int. Cl. G01N 21/47; G03F 7/00

(52) U.S. Cl. CPC G01N 21/4738; G03F 7/7055; G03F 7/70625; G03F 7/706849

(57) ABSTRACT

This application discloses a method for monitoring a ghost image of a illumination unit of a lithography machine, which includes step 1: setting a lens area, a peripheral area, and a central area on a moving plane of a measurement platform; light leakage in the peripheral area causing a ghost image; step 2: turning on the illumination unit, moving the measurement platform to move the light intensity uniformity sensor to the central area, measuring first light intensity in the central area, and obtaining a reference value from the first light intensity; step 3: moving the light intensity uniformity sensor to a selected position in the peripheral area and measuring second light intensity at the selected position; and step 4: dividing the second light intensity by the reference value to obtain a first ratio as a scattered light monitoring value for the ghost image.

### CROSS-REFERENCE TO RELATED APPLICATIONS

This application claims the priority to Chinese patent application No. 202311112388.X, filed on Aug. 30, 2023, the disclosure of which is incorporated herein by reference in entirety.

### TECHNICAL FIELD

This application relates to a method for manufacturing a semiconductor integrated circuit, in particular to a method for monitoring a ghost image of a illumination unit of a lithography machine.

### BACKGROUND

Referring to FIG. 1A, it illustrates a schematic diagram of a mask in an existing lithography process. The mask 101 includes a main pattern area 102. There is a peripheral pattern area 103 on a periphery of the main pattern area 102.

There is a pattern 104 in the main pattern area 102, and a pattern 105 in the peripheral pattern area 103.

In a lithography machine such as a scanner lithography machine, it is necessary to transfer the pattern 104 in the main pattern area 102 to a shot on a wafer during first exposure. However, due to the presence of the peripheral pattern area 103, scattered light from a light source may pass through the peripheral pattern area 103 and transfer the pattern 105 of the peripheral pattern area 103 to an adjacent shot, thus affecting the pattern in the adjacent shot. This effect is called ghost image effect.

Referring to FIG. 1B, it illustrates a schematic diagram of a ghost image in an existing lithography process. In the lithography process, a shot 107a is firstly exposed to form a pattern 104a in the shot 107a that is transferred from the pattern 104 in the main pattern area 102 of the mask 101.

Afterwards, the shot 107b is exposed. At this time, the pattern 104 is transferred to the shot 107b to form the pattern 104b. However, in this process, light from the light source and passing through a lens does not only enter the main pattern area 102, but also scattered light 106 will pass through the peripheral pattern area 103, and then light 106a will enter the shot 107a adjacent to the shot 107b. At this time, the pattern 105 in the peripheral pattern area 103 will be transferred to the shot 107a to form a pattern 105a. Obviously, the pattern 105a will affect the already formed pattern 104a. For example, it may cause a change in the critical dimension (CD) of the pattern 104a. The effect of forming the pattern 105a in the adjacent shot 107a by the scattered light 106 is called ghost image effect.

The existing method for monitoring the ghost image of the illumination unit of the lithography machine utilize the double exposure effect in the shot 107a illustrated in FIG. 1B. The existing method for monitoring the ghost image of the illumination unit of the lithography machine include the following steps:

First exposure is performed on the shot 107a to form a pattern 104a. The CD of the pattern 104a after first exposure is measured.

Next, the shot 107b is exposed. At this time, due to the ghost image effect, the scattered light 106 in the exposure will cause second exposure to the shot 107a and overlay the pattern 105a on the basis of the pattern 104a. The pattern 105a will change the critical dimension of the pattern 104a. At the same time, the change in the critical dimension of the pattern 104a is calculated to calculate the amount of light leakage, thus monitoring the ghost image.

However, the existing method for monitoring the ghost image of illumination unit of the lithography machine has the following disadvantages:

Firstly, it is necessary to establish specific exposure conditions to worsen the ghost image, so that the scattered light intensity reaches a threshold before it can be detected, and the sensitivity is too low.

Secondly, the range that the existing method can monitor is strongly related to the size of the mask 101 itself, so that the monitoring range is limited.

Thirdly, since the existing method indirectly monitors light leakage by measuring CD on wafers, multiple steps such as photoresist coating, exposure, development, and measurement are required, so that the entire period is long.

Finally, the measurement of CD relies on the principle of electron beam imaging, and the stability of the electron beam and the measurement problems may cause interference to the measurement result, so that the accuracy of the final result is reduced.

### BRIEF SUMMARY

According to some embodiments in this application, a method for monitoring the ghost image of the illumination unit of the lithography machine is disclosed in the following steps:
step 1: the illumination unit of the lithography machine including a lens and a measurement platform, a light intensity uniformity sensor being provided on the measurement platform;
setting a lens area, a peripheral area, and a central area on a moving plane of the measurement platform; the lens area being located in an internal area of an edge line formed after illuminating an edge of the lens, the central area being a selected area within the lens area, a center point of the central area being a center point of the lens area; the peripheral area being located on an outer side of the lens area, light leakage in the peripheral area causing a ghost image;
step 2: turning on the illumination unit, moving the measurement platform to move the light intensity uniformity sensor to the central area, measuring first light intensity in the central area, and obtaining a reference value from the first light intensity;
step 3: moving the measurement platform to move the light intensity uniformity sensor to a selected position in the peripheral area, and measuring second light intensity at the selected position in the peripheral area; and
step 4: dividing the second light intensity by the reference value to obtain a first ratio as a scattered light monitoring value for the ghost image.

In some cases, in step 4, the first ratio is multiplied by 100 or 100% as the scattered light monitoring value.

In some cases, the measurement platform is moved stepwise along an X or Y direction.

In some cases, a step size for moving the measurement platform along the X direction is a first step, and the size of the first step is pre-set before step 2 and adjustable;
a step size for moving the measurement platform along the Y direction is a second step, and the size of the second step is pre-set before step 2 and adjustable.

In some cases, the coordinates of the selected position in step 3 are changed, and then step 3 and step 4 are repeated to obtain the scattered light monitoring values at the selected positions with different coordinates.

In some cases, the coordinates of the selected position in step 3 are continuously changed by moving stepwise along the X or Y direction to achieve the measurement of the scattered light monitoring value at each position in a sub-area of the peripheral area.

In some cases, the coordinates of the selected position in step 3 are continuously changed by moving stepwise along the X or Y direction to achieve the measurement of the scattered light monitoring values at all positions in the peripheral area.

In some cases, the illumination unit further includes a light source, and the wavelength of the light source includes 365 nm, 248 nm, or 193 nm.

In some cases, the lithography machine is a scanner lithography machine.

In some cases, the size of a wafer exposed by the lithography machine includes 200 nm, 300 nm, or 450 nm.

In some cases, in step 2, the moving direction and distance of the measurement platform are continuously changed by moving stepwise along the X or Y direction to achieve the measurement of the first light intensity at all positions in the central area, and the average value of the first light intensity at all positions in the central area is used as the reference value.

In some cases, the method further includes:
step 5: moving the measurement platform to move the light intensity uniformity sensor to the lens area outside the central area to achieve the measurement of third light intensity in the lens area outside the central area.

In some cases, in step 5, the moving direction and distance of the measurement platform are continuously changed by moving stepwise along the X or Y direction to achieve the measurement of the third light intensity at all positions in the lens area outside the central area.

This application uses the light intensity uniformity sensor of the lithography machine to monitor the peripheral scattered light leakage ratio of the lens of the lithography machine, infers the ghost image of the illumination unit, and can achieve the following technical effects:

1. This application can improve the sensitivity. In the existing method, it is necessary to compare and calculate the critical dimensions of the patterns in the two-time shot and the single-time shot to calculate the amount of light leakage and monitor the ghost image. In the existing method, specific exposure conditions need to be set to worsen the ghost image, so that the scattered light intensity reaches a threshold or above before it can be detected, resulting in low sensitivity. However, in this application, the light intensity uniformity sensor itself has high photoelectric sensitivity, so monitoring can be achieved without setting specific conditions. Therefore, this application can improve the sensitivity.

2. This application can expand the monitoring range. In the existing method, the monitoring requires the use of a mask for exposure, and the monitoring range is limited by the size of the mask. However, in this application, there is no need to use a mask in the monitoring process. The light intensity uniformity sensor is mounted on the measurement platform, which has a large range of movement. Therefore, the area with the ghost image that this application can monitor is wider, thus expanding the monitoring range.

3. This application can shorten the measurement period. In the existing method, it is necessary to measure and monitor the critical dimension (CD) on wafers, which requires multiple steps including photoresist coating, exposure, development, and measurement, resulting in a long period. However, in this application, the light intensity uniformity sensor is used for direct measurement and monitoring, thus shortening the measurement period.

4. This application can achieve the repeated measurement, effectively eliminate the measurement error, and improve the accuracy. In the existing method, the measurement of CD on wafers is based on the principle of electron beam imaging. The stability and measurement problems of the electron beam may cause interference to the measurement result and reduce the accuracy of the result. However, in this application, the light intensity uniformity sensor is used for direct measurement and monitoring, thus achieving the repeated measurement, effectively eliminating the measurement error, and improving the accuracy.

### BRIEF DESCRIPTION OF THE DRAWINGS

This application will be further described below in combination with the specific embodiments with reference to the drawings.

FIG. 1A illustrates a schematic diagram of a mask in an existing lithography process.

FIG. 1B illustrates a schematic diagram of a ghost image in an existing lithography process.

FIG. 2 illustrates a flowchart of a method for monitoring a ghost image of an illumination unit of a lithography machine according to an embodiment of this application.

FIG. 3A illustrates a schematic diagram of a lens area, a peripheral area and a central area in a method for monitoring a ghost image of an illumination unit of a lithography machine according to an embodiment of this application.

FIG. 3B illustrates a schematic diagram of measurement of light intensity by adopting a light intensity uniformity sensor in a method for monitoring a ghost image of an illumination unit of a lithography machine according to an embodiment of this application.

FIG. 4A illustrates a schematic diagram of light intensity testing by moving a measurement platform along an X-axis direction in a method for monitoring a ghost image of an illumination unit of a lithography machine according to an embodiment of this application.

FIG. 4B illustrates a light intensity distribution curve obtained through light intensity testing by moving a measurement platform along an X-axis direction in FIG. 4A.

FIG. 5A illustrates a schematic diagram of scanning in a sub-area in a method for monitoring a ghost image of an illumination unit of a lithography machine according to an embodiment of this application.

FIG. 5B illustrates a light intensity distribution table obtained through scanning in a sub-area in FIG. 5A.

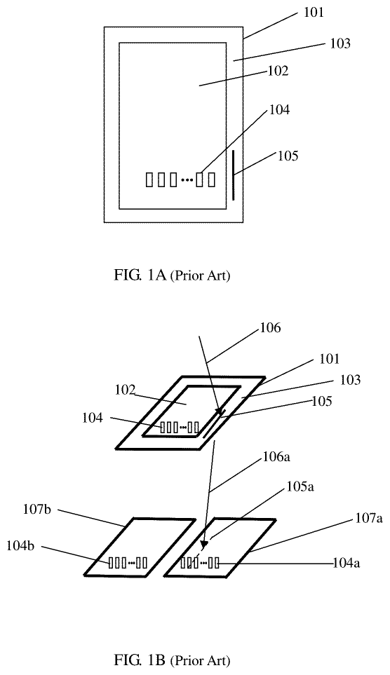

### DETAILED DESCRIPTION OF THE APPLICATOIN

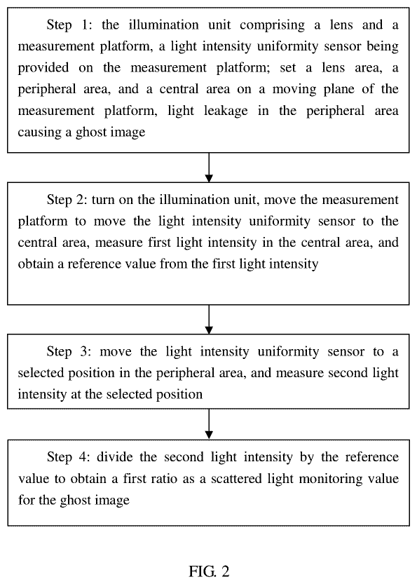

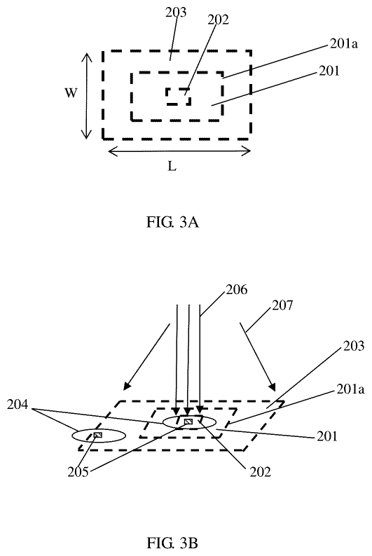

Referring to FIG. 2, it illustrates a flowchart of a method for monitoring a ghost image of a illumination unit of a lithography machine according to an embodiment of this application. Referring to FIG. 3A, it illustrates a schematic diagram of a lens area 201, a peripheral area 203 and a central area 202 in a method for monitoring a ghost image of an illumination unit of a lithography machine according to an embodiment of this application. Referring to FIG. 3B, it illustrates a schematic diagram of measurement of light intensity by adopting a light intensity uniformity sensor 205 in a method for monitoring a ghost image of an illumination unit of a lithography machine according to an embodiment of this application. A method for monitoring a ghost image of an illumination unit of a lithography machine according to an embodiment of this application includes the following steps:

In step 1, the illumination unit of the lithography machine includes a lens and a measurement platform 204, and a light intensity uniformity sensor 205 is provided on the measurement platform 204.

Referring to FIG. 3A, a lens area 201, a peripheral area 203, and a central area 202 are set on a moving plane of the measurement platform 204. The lens area 201 is located in an internal area of an edge line 201 formed after illuminating an edge of the lens. The central area 202 is a selected area within the lens area 201. A center point of the central area 202 is a center point of the lens area 201. The peripheral area 203 is located on an outer side of the lens area 201. Light leakage in the peripheral area 203 causes a ghost image.

In FIG. 3A, the length of the outer circumference of the peripheral area 203 is L and the width is W. The direction of the length Lis an X direction. The direction of the width W is a Y direction.

In this embodiment of this application, the illumination unit further includes a light source, and the wavelength of the light source includes 365 nm, i.e., in-line light, 248 nm, i.e., KeF light, or 193 nm, i.e., ArF light.

The lithography machine is a scanner lithography machine.

The size of a wafer exposed by the lithography machine includes 200 nm, 300 nm, or 450 nm.

In step 2, referring to FIG. 3B, the illumination unit is turned on. FIG. 3B illustrates vertically illuminating light 206 and scattered light 207 on an edge. The scattered light 207 causes a ghost image.

The measurement platform 204 is moved to move the light intensity uniformity sensor 205 to the central area 202. First light intensity in the central area 202 is measured. A reference value is obtained from the first light intensity. FIG. 3B illustrates only one measurement platform 204. However, in order to simultaneously represent that the measurement platform 204 can move in various positions, a schematic diagram of the measurement platform 204 at two positions is displayed.

In step 3, referring to FIG. 3B, the measurement platform 204 is moved to move the light intensity uniformity sensor 205 to a selected position in the peripheral area 203, and second light intensity at the selected position in the peripheral area 203 is measured.

In step 4, the second light intensity is divided by the reference value to obtain a first ratio as a scattered light monitoring value for the ghost image.

In this embodiment of this application, the first ratio is multiplied by 100 or multiplied by 100% as the scattered light monitoring value, which is expressed by adopting the following formula:

Scattered light=measured value/reference value*100[%] (1)

In formula (1), the scattered light is the scattered light monitoring value, and the measured value is the second light intensity.

The measurement platform 204 is moved stepwise along the X or Y direction. Referring to FIG. 3A, the X direction is the direction of the length L, and the Y direction is the direction of the width W.

A step size for moving the measurement platform 204 along the X direction is a first step, and the size of the first step is pre-set before step 2 and adjustable.

A step size for moving the measurement platform 204 along the Y direction is a second step, and the size of the second step is pre-set before step 2 and adjustable.

In this embodiment of this application, the coordinates of the selected position in step 3 are changed, and then step 3 and step 4 are repeated to obtain the scattered light monitoring values at the selected positions with different coordinates.

In some embodiments, the coordinates of the selected position in step 3 are continuously changed by moving stepwise along the X or Y direction to achieve the measurement of the scattered light monitoring value at each position in a sub-area of the peripheral area 203.

In some embodiments, the coordinates of the selected position in step 3 are continuously changed by moving stepwise along the X or Y direction to achieve the measurement of the scattered light monitoring values at all positions in the peripheral area 203.

In some embodiments, the moving direction and distance of the measurement platform 204 are continuously changed by moving stepwise along the X or Y direction to achieve the measurement of the first light intensity at all positions in the central area 202, and the average value of the first light intensity at all positions in the central area 202 is used as the reference value.

In some embodiments, the method further includes the following step:

In step 5, the measurement platform 204 is moved to move the light intensity uniformity sensor 205 to the lens area 201 outside the central area 202 to achieve the measurement of third light intensity in the lens area 201 outside the central area 202.

In some cases, in step 5, the moving direction and distance of the measurement platform 204 are continuously changed by moving stepwise along the X or Y direction to achieve the measurement of the third light intensity at all positions in the lens area 201 outside the central area 202.

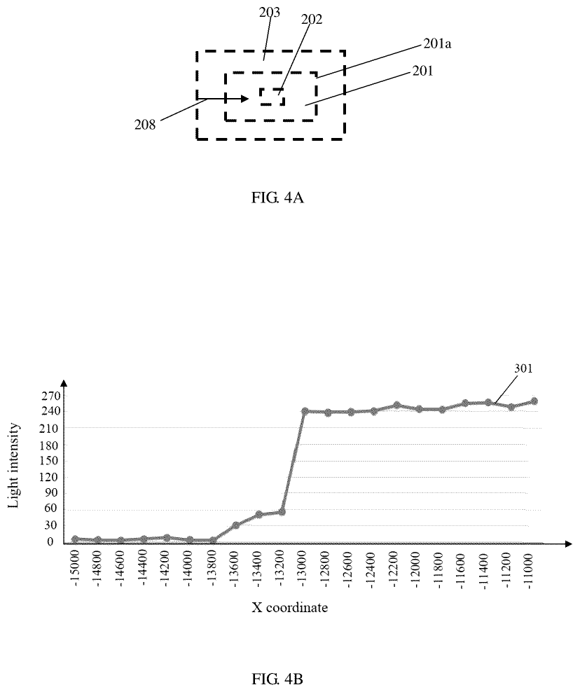

Referring to FIG. 4A, it illustrates a schematic diagram of light intensity testing by moving a measurement platform along an X-axis direction in a method for monitoring a ghost image of an illumination unit of a lithography machine according to an embodiment of this application. That is, starting from the outer edge of the peripheral area 203, the measurement platform is moved by the first step along the X-axis direction and is moved all the way to the lens area 201. The light intensity at each moving position is tested. Referring to FIG. 4B, it illustrates a light intensity distribution curve 301 obtained through light intensity testing by moving a measurement platform along an X-axis direction in FIG. 4A. It can be seen that there is certain light intensity in the peripheral area 203 when the X coordinate is between −13800 and −13200, and the light intensity in the area beyond the coordinate of −13800 is basically 0. The area in the coordinate of −13200 is the lens area 201, and the corresponding light intensity is the third light intensity.

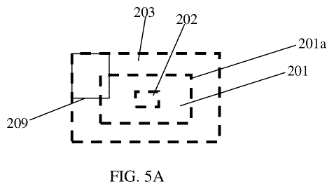

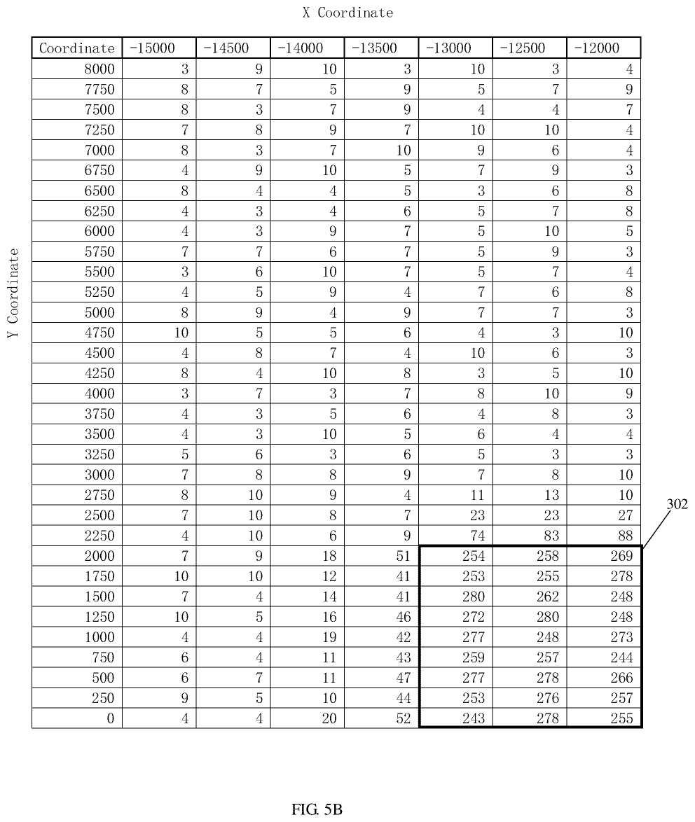

Referring to FIG. 5A, it illustrates a schematic diagram of scanning in a sub-area in a method for monitoring a ghost image of an illumination unit of a lithography machine according to an embodiment of this application. In FIG. 5A, a sub-area 209 is an area where scanning is required to measure light intensity. The most part of the sub-area 209 is located in the peripheral area 203, and a small part is located in the lens area 201. Referring to FIG. 5B, it illustrates a light intensity distribution table obtained through scanning in a sub-area 209 in FIG. 5A. In FIG. 5B, an area illustrated in box 302 is located in the lens area 201. It can be seen that the light intensity is relatively high in the peripheral area near box 302, such as the two first step areas in the X direction and the two second step areas in the Y direction; the light intensity in the other external area of the peripheral area 203 is relatively low, which is consistent with the curve 301 in FIG. 4B.

This embodiment of this application uses the light intensity uniformity sensor 205 of the lithography machine to monitor the peripheral scattered light leakage ratio of the lens of the lithography machine, infers the ghost image of the illumination unit, and can achieve the following technical effects:

1. This embodiment of this application can improve the sensitivity. In the existing method, it is necessary to compare and calculate the critical dimensions of the patterns in the two-time shot and the single-time shot to calculate the amount of light leakage and monitor the ghost image. In the existing method, specific exposure conditions need to be set to worsen the ghost image, so that the scattered light intensity reaches a threshold or above before it can be detected, resulting in low sensitivity. However, in this embodiment of this application, the light intensity uniformity sensor 205 itself has high photoelectric sensitivity, so monitoring can be achieved without setting specific conditions. Therefore, this embodiment of this application can improve the sensitivity.

2. This embodiment of this application can expand the monitoring range. In the existing method, the monitoring requires the use of a mask for exposure, and the monitoring range is limited by the size of the mask. However, in this embodiment of this application, there is no need to use a mask in the monitoring process. The light intensity uniformity sensor 205 is mounted on the measurement platform 204, which has a large range of movement. Therefore, the area with the ghost image that this embodiment of this application can monitor is wider, thus expanding the monitoring range.

3. This embodiment of this application can shorten the measurement period. In the existing method, it is necessary to measure and monitor the critical dimension (CD) on wafers, which requires multiple steps including photoresist coating, exposure, development, and measurement, resulting in a long period. However, in this embodiment of this application, the light intensity uniformity sensor 205 is used for direct measurement and monitoring, thus shortening the measurement period.

4. This embodiment of this application can achieve the repeated measurement, effectively eliminate the measurement error, and improve the accuracy. In the existing method, the measurement of CD on wafers is based on the principle of electron beam imaging. The stability and measurement problems of the electron beam may cause interference to the measurement result and reduce the accuracy of the result. However, in this embodiment of this application, the light intensity uniformity sensor 205 is used for direct measurement and monitoring, thus achieving the repeated measurement, effectively eliminating the measurement error, and improving the accuracy.

This application has been described in detail above through the specific embodiments, which, however, do not constitute limitations to this application. Without departing from the principles of this application, those skilled in the art may also make many modifications and improvements, which should also be considered as included in the scope of protection of this application.

What is claimed is:

1. A method for monitoring a ghost image of an illumination unit of a lithography machine, comprising:
step 1: the illumination unit of the lithography machine comprising a lens and a measurement platform, a light intensity uniformity sensor being provided on the measurement platform;
setting a lens area, a peripheral area, and a central area on a moving plane of the measurement platform; the lens area being located in an internal area of an edge line formed after illuminating an edge of the lens, the central area being a selected area within the lens area, a center point of the central area being a center point of the lens area; the peripheral area being located on an outer side of the lens area, light leakage in the peripheral area causing the ghost image;
step 2: turning on the illumination unit, moving the measurement platform to move the light intensity uniformity sensor to the central area, measuring first light intensity in the central area, and obtaining a reference value from the first light intensity;
step 3: moving the measurement platform to move the light intensity uniformity sensor to a selected position in the peripheral area, and measuring second light intensity at the selected position in the peripheral area; and
step 4: dividing the second light intensity by the reference value to obtain a first ratio as a scattered light monitoring value for the ghost image.

2. The method for monitoring the ghost image of the illumination unit of the lithography machine according to claim 1, wherein, in step 4, the first ratio is multiplied by 100 or 100% as the scattered light monitoring value.

3. The method for monitoring the ghost image of the illumination unit of the lithography machine according to claim 1, wherein the measurement platform is moved stepwise along an X direction or a Y direction.

4. The method for monitoring the ghost image of the illumination unit of the lithography machine according to claim 3, wherein a step size for moving the measurement platform along the X direction is a first step, and a size of the first step is pre-set before step 2 and is adjustable; and
a step size for moving the measurement platform along the Y direction is a second step, and a size of the second step is pre-set before step 2 and is adjustable.

5. The method for monitoring the ghost image of the illumination unit of the lithography machine according to claim 4, wherein coordinates of the selected position in step 3 are changed, and then step 3 and step 4 are repeated to obtain scattered light monitoring values at selected positions with different coordinates.

6. The method for monitoring the ghost image of the illumination unit of the lithography machine according to claim 5, wherein the coordinates of the selected position in step 3 are continuously changed by moving stepwise along the X direction or the Y direction to achieve a measurement of a scattered light monitoring value at each position in a sub-area of the peripheral area.

7. The method for monitoring the ghost image of the illumination unit of the lithography machine according to claim 6, wherein the coordinates of the selected position in step 3 are continuously changed by moving stepwise along the X direction or the Y direction to achieve the measurement of scattered light monitoring values at all positions in the peripheral area.

8. The method for monitoring the ghost image of the illumination unit of the lithography machine according to claim 1, wherein the illumination unit further comprises a light source, and a wavelength of the light source comprises 365 nm, 248 nm, or 193 nm.

9. The method for monitoring the ghost image of the illumination unit of the lithography machine according to claim 1, wherein the lithography machine is a scanner lithography machine.

10. The method for monitoring the ghost image of the illumination unit of the lithography machine according to claim 1, wherein a size of a wafer exposed by the lithography machine comprises 200 nm, 300 nm, or 450 nm.

11. The method for monitoring the ghost image of the illumination unit of the lithography machine according to claim 4, wherein, in step 2, a moving direction and distance of the measurement platform are continuously changed by moving stepwise along the X direction or the Y direction to achieve a measurement of the first light intensity at all positions in the central area, and an average value of the first light intensity at all positions in the central area is used as the reference value.

12. The method for monitoring the ghost image of the illumination unit of the lithography machine according to claim 4, wherein the method further comprises:
step 5: moving the measurement platform to move the light intensity uniformity sensor to the lens area outside the central area to achieve a measurement of third light intensity in the lens area outside the central area.

13. The method for monitoring the ghost image of the illumination unit of the lithography machine according to claim 12, wherein, in step 5, a moving direction and distance of the measurement platform are continuously changed by moving stepwise along the X direction or the Y direction to achieve the measurement of the third light intensity at all positions in the lens area outside the central area.
